(19) United States
(12) Patent Application Publication
(10) Pub. No.: US 2026/0118385 A1
(43) Pub. Date: Apr. 30, 2026

(54) CONTACT PROBE, PROBE HEAD, PROBE CARD AND PROBE SYSTEM

(71) Applicant: MPL CORPORATION, Zhubei City (TW)

(72) Inventors: Hsin-Hung LIN, Zhubei City (TW); Chin-Tien YANG, Zhubei City (TW); Hui-Pin YANG, Zhubei City (TW); Hsien-Ta HSU, Zhubei City (TW)

(21) Appl. No.: 19/369,700

(22) Filed: Oct. 27, 2025

Related U.S. Application Data
(60) Provisional application No. 63/712,625, filed on Oct. 28, 2024.

(51) Int. Cl. G01R 1/073

(52) U.S. Cl. CPC G01R 1/07378; G01R 1/07342

(57) ABSTRACT

A contact probe comprises a probe body, a through groove, a first stop portion and an insulating layer. The probe body extends along a longitudinal direction, and includes a needle tip portion and a needle tail portion that are respectively located at two opposite ends thereof along the longitudinal direction, and a first side surface and a second side surface that are respectively located at two opposite ends in a first transverse direction. The through groove runs through the probe body along a second transverse direction and extends along the longitudinal direction. The first stop portion protrudes only from the first side surface along the first transverse direction and is located at the needle tail portion of the probe body. The insulating layer is a metal oxide and is disposed on an outer surface of the first stop portion, thereby reducing a thickness and a width of the contact probe at the first stop portion, preventing electrical errors caused by contact during operation, and improving durability and reliability of the overall structure.

### CROSS-REFERENCE TO RELATED APPLICATION

This application claims the benefit of U.S. Provisional Patent Application No. 63/712,625, filed on Oct. 28, 2024, the entire disclosure of which is incorporated by reference herein.

### FIELD

The present invention is related to a testing apparatus for testing electronic devices, and more particularly to a contact probe, probe head, probe card and probe system for testing electronic devices.

### BACKGROUND

Referring to FIG. 1 and FIG. 2, a probe card 11 is a testing tool used in the semiconductor field, mainly used to detect electrical characteristics of a semiconductor component 19 on a wafer. The probe card 11 typically includes a main circuit board 12, a space transformer 13, a guide plate unit 14 having a plurality of guide holes 141, and a plurality of contact probes 15 passing through the guide holes 141. During testing, the contact probes 15 contact electrode pads 191 on the semiconductor component 19. The main circuit board 12 transmits test signals to the semiconductor component 19 through the space transformer 13 and the contact probes 15 to perform testing. As shown in FIG. 2, in order to prevent the contact probes 15 from falling out of the guide holes 141, an upper end of each of the contact probes 15 is formed with a top portion 151 that protrudes from the guide hole 141.

As the process size continues to shrink, the size and spacing of the electrode pads 191 of the semiconductor component 19 continue to decrease. Therefore, the size and spacing of the contact probes 15 must also be reduced to meet requirements of high-density testing layouts. However, while the size of the contact probes 15 is reduced, the contact probes 15 must still maintain sufficient conductivity and mechanical strength, and must not contact each other. These limitations constitute physical limits of the contact probes 15 in terms of size and spacing reduction.

### SUMMARY

Therefore, the present invention provides a contact probe that is capable of reducing spacing.

Thus, the contact probe of the present invention is adapted for contacting and testing a device under test and comprises a probe body, a through groove, a first stop portion and an insulating layer.

The probe body extends along a longitudinal direction. A first transverse direction is defined as intersecting the longitudinal direction, and a second transverse direction is defined as intersecting the longitudinal direction and the first transverse direction. The probe body includes a needle tip portion and a needle tail portion respectively located at two opposite ends thereof along the longitudinal direction, and a first side surface and a second side surface respectively located at two opposite ends in the first transverse direction. The needle tip portion is adapted to contact the device under test.

The through groove runs through the probe body along the second transverse direction and extends along the longitudinal direction.

The first stop portion protrudes only from the first side surface along the first transverse direction and is located at the needle tail portion of the probe body.

The insulating layer is a metal oxide and is disposed on an outer surface of the first stop portion.

Therefore, the present invention provides a probe head that is capable of reducing spacing between contact probes.

Thus, the probe head of the present invention is adapted for contacting and testing a device under test and comprises an upper guide plate module, a lower guide plate module, a middle guide plate module, and a plurality of contact probes as described above.

The upper guide plate module includes a plurality of upper guide holes.

The lower guide plate module and the upper guide plate module are spaced apart along a longitudinal direction. The lower guide plate module includes a plurality of lower guide holes. Positions of the lower guide holes respectively correspond to positions of the upper guide holes.

The middle guide plate module is disposed between the upper guide plate module and the lower guide plate module, thereby spacing apart the upper guide plate module and the lower guide plate module.

Each of the contact probes passes through one of the upper guide holes and a corresponding one of the lower guide holes.

Therefore, the present invention provides a probe card that is capable of reducing spacing between contact probes.

Thus, the probe card of the present invention is adapted for contacting and testing a device under test and comprises a main circuit board, a space transformer and a probe head as described above.

The space transformer is electrically connected to the main circuit board and includes a plurality of signal contact pads.

In the probe head, the needle tail portions of the contact probes are respectively used for contacting the signal contact pads.

Therefore, the present invention provides a probe system that is capable of reducing spacing between contact probes.

Thus, the probe system of the present invention is adapted for contacting and testing a device under test. The device under test includes a plurality of contact points. The probe system comprises a carrier unit, a testing machine and the probe card as described above.

The carrier unit is adapted for the device under test to be disposed thereon.

The testing machine is used for executing a testing program and outputting a program signal.

The probe card is disposed to correspond to the carrier unit. In the probe card, the contact probes are adapted to contact the contact points. The main circuit board is signally connected to the testing machine, receives the program signal, outputs a testing signal based on the program signal, and transmits the testing signal via the space transformer and the contact probes to test the device under test.

The effects of the present invention reside in that: by providing the through groove in the probe body, providing the first stop portion at the needle tail portion, and forming the insulating layer of metal oxide on the outer surface of the first stop portion, the present invention is not only capable of reducing the radial width and thickness of the contact probe at the first stop portion (especially at the needle tail portion), but also ensures that even if the first stop portion approaches or contacts an adjacent contact probe due to bending during operation, no electrical errors will occur. Thus, the spacing between the contact probes may be further reduced while maintaining body structure size and conductivity of the contact probes.

### BRIEF DESCRIPTION OF DRAWINGS

Other features and effects of the present invention will be apparently presented in the embodying manner with reference to the drawings, in which:

FIG. 1 is a schematic diagram of a conventional probe card;

FIG. 2 is a top view of a plurality of conventional contact probes disposed in a plurality of guide holes;

FIG. 3 is a schematic diagram of a partial cross-section of an embodiment of a probe system of the present invention;

FIG. 4 is a perspective schematic diagram of a contact probe of the embodiment.

FIG. 5 is a top view of the contact probes of the embodiment disposed in a plurality of upper guide holes;

FIG. 6 is a schematic diagram of the embodiment, illustrating the arrangement relationship between the contact probes and a plurality of contact points;

FIG. 7 is a side view of a second configuration of the contact probe of the embodiment;

FIG. 8 is a perspective view of a third configuration of the contact probe of the embodiment;

FIG. 9 is a top view of the contact probes of the third configuration of the embodiment disposed in the upper guide holes;

FIG. 10 is a side view of the contact probe of the third configuration of the embodiment disposed in the upper guide hole and a lower guide hole;

FIG. 11 is a top view illustrating a variation of the contact probes of the third configuration of the embodiment;

FIG. 12 is a perspective schematic diagram of a fourth configuration of the contact probe of the embodiment;

FIG. 13 is a top view of the contact probes of the fourth configuration of the embodiment disposed in the upper guide holes;

FIG. 14 is a side view of the contact probe of the fourth configuration of the embodiment disposed in the upper guide hole and the lower guide hole; and

FIG. 15 and FIG. 16 are each a top view illustrating possible shapes of the contact probes of the fourth configuration of the embodiment resulting from processing errors.

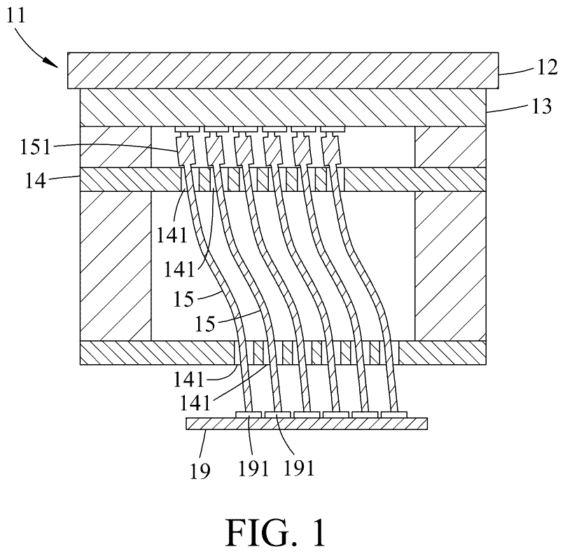

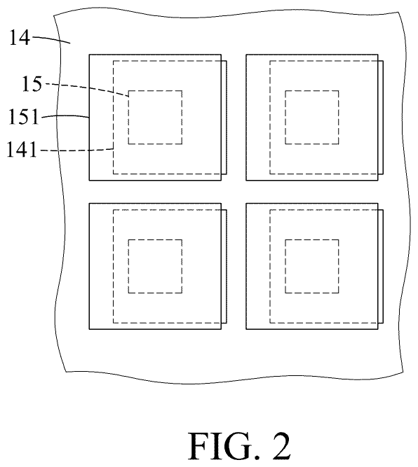

### DETAILED DESCRIPTION

Before the present invention is described in detail, it should be noted that similar elements are represented by the same numbers in the following description.

The term “substantially” as used in the present specification and claims, when “substantially” modifies a degree or relation, may include not only the stated “substantial” degree or relation, but also the entire range of the stated degree or relation. A substantial amount of a stated degree or relation may include at least 95% of the stated degree or relation. For example, the term “substantially equal to” as used in the present specification and claims means that the size difference between the two is within an allowable manufacturing tolerance range, or within a range that does not affect the technical effect of the present invention. The two can be considered “substantially equal” when the difference still makes the two exhibit equivalent effects.

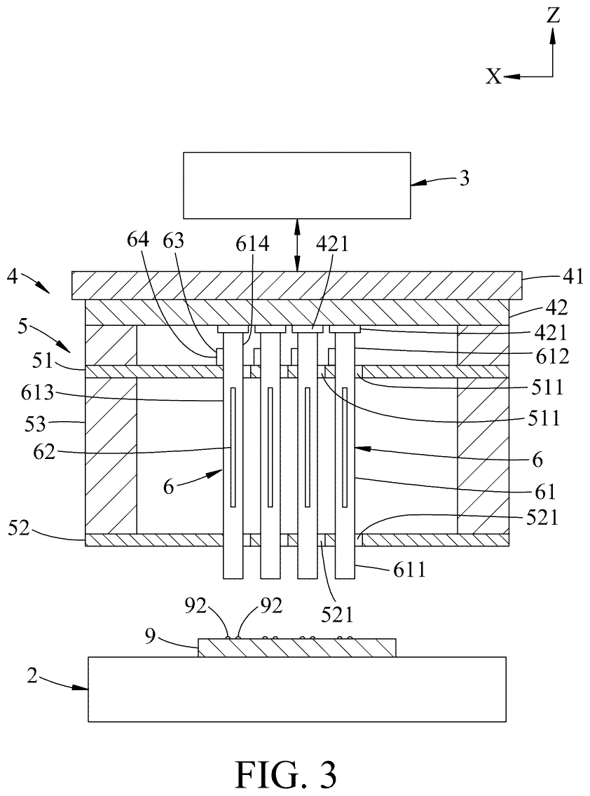

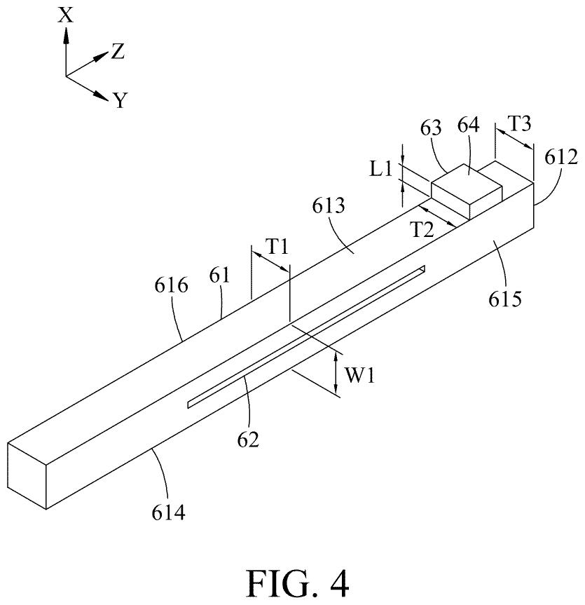

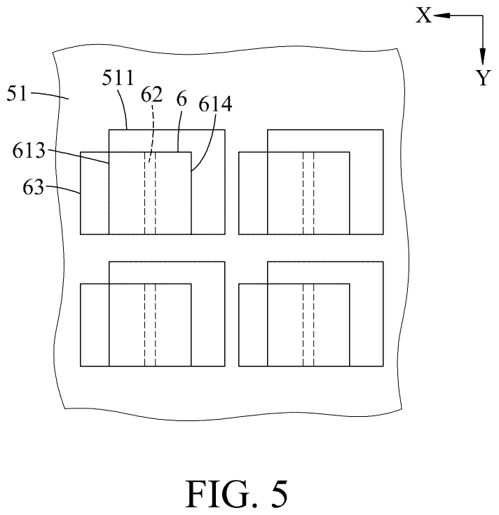

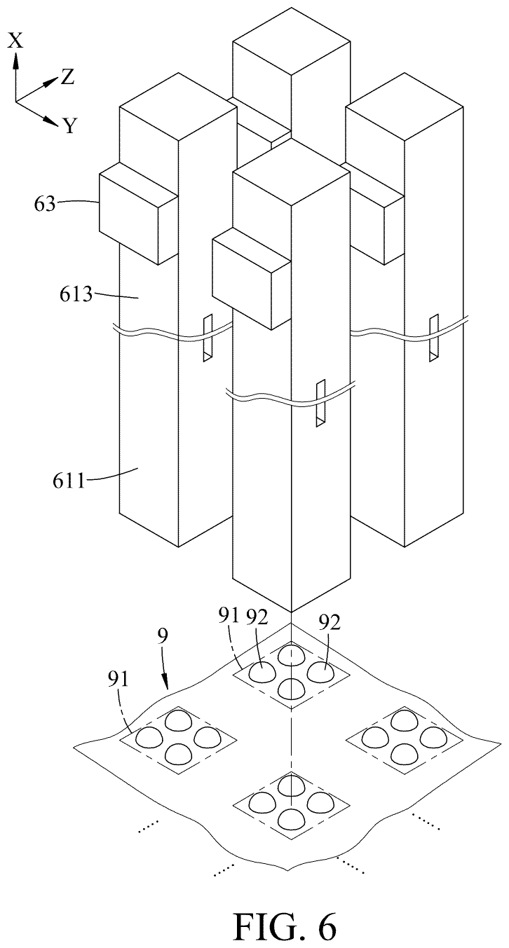

Referring to FIG. 3, FIG. 4, FIG. 5 and FIG. 6, an embodiment of a probe system of the present invention is adapted for testing one or more (electronic) devices under test (DUTs) 9 integrated on a semiconductor wafer. In the present embodiment, one of the devices under test 9 is described. The device under test 9 includes a plurality of probe contact blocks 91. Each of the probe contact blocks 91 has one or more contact points 92. The contact points 92 may be bumps or contact pads. The embodiment comprises a carrier unit 2, a testing machine 3 and a probe card (PC) 4.

The carrier unit 2 is adapted for the device under test 9 to be disposed thereon.

The testing machine 3 is used for executing a testing program and outputting a program signal.

The probe card 4 is disposed to correspond to the carrier unit 2 and includes a main circuit board 41, a space transformer (ST) 42 and a probe head 5.

The main circuit board 41 is signally connected to the testing machine 3. The space transformer 42 is electrically connected to the main circuit board 41 and is disposed between the probe head 5 and the main circuit board 41. A lower surface of the space transformer 42 has a plurality of signal contact pads 421 to provide electrical contact for the probe head 5. Spacing between the signal contact pads 421 is smaller than spacing between contact pads (not shown) on an upper surface of the space transformer 42 to provide electrical connection for the main circuit board 41. In this way, the space transformer 42 is used to perform space transforming between the probe head 5 and conductive contact points (not shown) of the main circuit board 41.

The probe head 5 has an upper guide plate module 51, a lower guide plate module 52, a middle guide plate module 53 and a plurality of contact probes 6.

The upper guide plate module 51 includes a plurality of upper guide holes 511 and may be implemented using a multi-layer guide plate. That is, the upper guide plate module 51 may have a plurality of guide plates.

The lower guide plate module 52 and the upper guide plate module 51 are spaced apart along a longitudinal direction Z, which is a longitudinal development axis. The lower guide plate module 52 includes a plurality of lower guide holes 521 respectively corresponding to the upper guide holes 511. The lower guide plate module 52 may be implemented using a multi-layer guide plate. That is, the lower guide plate module 52 may have a plurality of guide plates.

The middle guide plate module 53 is disposed between the upper guide plate module 51 and the lower guide plate module 52, thereby spacing apart the upper guide plate module 51 and the lower guide plate module 52.

Each of the contact probes 6 passes through one of the upper guide holes 511 and a corresponding one of the lower guide holes 521. The contact probes 6 are adapted for contacting the contact points 92 to test the device under test 9.

In application, the testing machine 3 executes the testing program and outputs the program signal to the main circuit board 41. The main circuit board 41 receives the program signal and outputs the testing signal based on the program signal. The testing signal is transmitted to the device under test 9 via the space transformer 42 and the contact probes 6 to test the device under test 9.

Each of the contact probes 6 has a probe body 61, a through groove 62, a first stop portion 63 and an insulating layer 64.

The probe body 61 extends along the longitudinal direction Z. A first transverse direction X is defined as intersecting the longitudinal direction Z, and a second transverse direction Y is defined as intersecting the longitudinal direction Z and the first transverse direction X. The probe body 61 has a width W1 along the first transverse direction X and a thickness T1 along the second transverse direction Y. The thickness T1 is greater than or equal to the width W1. That is, a transverse cross-section of the probe body 61 is square or rectangular. The probe body 61 includes a needle tip portion 611 and a needle tail portion 612 respectively located at two opposite ends thereof along the longitudinal direction Z, a first side surface 613 and a second side surface 614 respectively located at two opposite ends in the first transverse direction X, and a third side surface 615 and a fourth side surface 616 respectively located at two opposite ends in the second transverse direction Y. The third side surface 615 and the fourth side surface 616 are adjacent to the first side surface 613 and the second side surface 614.

The needle tip portion 611 is adapted to contact the device under test 9. In at least some of the contact probes 6, the needle tip portion 611 contacts a plurality of the contact points 92. That is, in at least some of the contact probes 6, the needle tip portion 611 contacts multiple ones of the contact points 92 simultaneously, while in the remaining ones of the contact probes 6, the needle tip portion 611 contacts one of the contact points 92. The needle tail portions 612 are respectively for contacting the signal contact pads 421. As shown in FIG. 5, in application, the first side surface 613 of each of the contact probes 6 abuts against a hole wall surface of the upper guide plate module 51 that defines the upper guide hole 511. That is, a side of the contact probe 6 that is thicker in width abuts against the upper guide plate module 51.

The through groove 62 runs through the probe body 61 along the second transverse direction Y and extends along the longitudinal direction Z. A height of a highest point of the through groove 62 in the longitudinal direction Z is lower than a height of a lowest point of the first stop portion 63 in the longitudinal direction Z. That is, a position of the through groove 62 in the longitudinal direction Z is below the first stop portion 63. Generally speaking, the position of the through groove 62 in the longitudinal direction Z is between the upper guide plate module 51 and the lower guide plate module 52.

The first stop portion 63 protrudes only from the first side surface 613 along the first transverse direction X and is located at the needle tail portion 612 of the probe body 61. The first stop portion 63 has a thickness T2 along the second transverse direction Y. The thickness T2 is substantially equal to (or less than) a thickness T3 of the needle tail portion 612 extending along the second transverse direction Y, substantially equal to (or less than) the thickness T1 of the probe body 61 extending along the second transverse direction Y, or substantially equal to (or less than) both of the above. A length L1 of the first stop portion 63 protruding from the first side surface 613 is less than the thickness T2.

To prevent interference between adjacent needles, the present invention reduces the size (i.e., the amount of protrusion) of the first stop portion 63. However, this will reduce the function of preventing dislodgement. It is necessary to provide the through groove 62 so that the needle tail portion 612 may tilt slightly in a controllable manner, so as to improve the fit between the first side surface 613 and the hole wall surface of the upper guide hole 511. However, the slight tilting action causes the needle tail portion 612 to shift towards the adjacent needle, further shortening a distance between the needle tail portion 612 and the adjacent contact probe 6. In a high-density arrangement, the first stop portion 63 is more likely to come into contact with the adjacent contact probe 6 and create a risk of electrical short circuit. Therefore, the present invention provides the insulating layer 64 (metal oxide) on the outer surface of the first stop portion 63 to ensure that even when the contact probes 6 are close to or in contact with one another due to slight tilting, a short circuit will not occur and affect testing reliability.

The term “substantially equal to” here means, for example, when a difference between the thickness T2 of the first stop portion 63 along the second transverse direction Y and the thickness T3 of the needle tail portion 612 extending along the second transverse direction Y, or a difference between the thickness T2 of the first stop portion 63 along the second transverse direction Y and the thickness T1 of the probe body 61 extending along the second transverse direction Y, does not exceed ±5%, or when the difference still allows the two components to have the same effects in preventing dislodgment, in securing, and in cooperating with the upper guide hole 511, it can be regarded as “substantially equal to”.

The insulating layer 64 is metal oxide and is disposed on an outer surface of the first stop portion 63 for providing the first stop portion 63 with insulation. In the drawings, the insulating layer 64 is directly indicated on the first stop portion 63 for illustration. A material of the insulating layer 64 may be, for example (but not limited to) metal oxides such as aluminum oxide, hafnium oxide and titanium dioxide. A method of coating the insulating layer 64 onto the surface of the first stop portion 63 may be (but is not limited to) physical vapor deposition, chemical vapor deposition, the sol-gel method, vapor deposition, atomic layer deposition, etc. In particular, the insulating layer 64 may be formed of a high-hardness insulating material. The high-hardness insulating material is, for example, a nitride or aluminum oxide. Specifically, the Vickers hardness of the insulating layer 64 is greater than a material hardness of the probe body 61. Specifically, the Vickers hardness of the insulating layer 64 is greater than a material hardness of the needle tail portion 612 of the probe body 61. When the insulating layer 64 is a high-hardness insulating material, in addition to preventing short circuits caused by adjacent contact probes 6 approaching or contacting each other, the high hardness also improves wear resistance and structural strength of the surface of the first stop portion 63, further enhancing the durability and reliability of the contact probe 6 under long-term testing cycles.

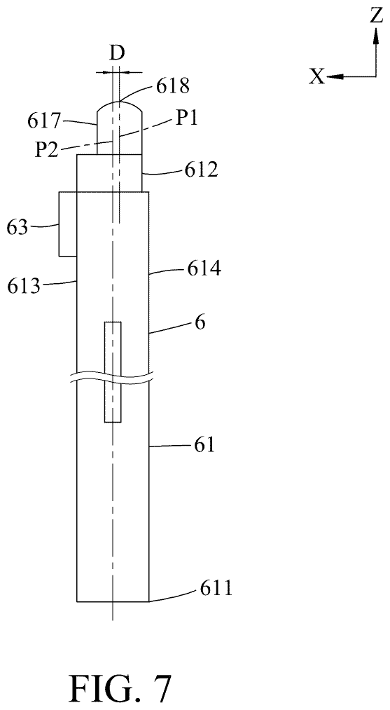

Referring to FIG. 3 and FIG. 7, a second configuration of the contact probe 6 of the embodiment is shown. In this second configuration of the contact probe 6, the needle tail portion 612 has a signal contact segment 617. The signal contact segment 617 is located at an end of the needle tail portion 612 that is away from the needle tip portion 611. A central axis P1 of the signal contact segment 617 has an offset amount D from a central axis P2 of the probe body 61 along the first transverse direction X. Furthermore, the central axis P1 of the signal contact segment 617 is closer to the second side surface 614 than the central axis P2 of the probe body 61 is to the second side surface 614. The central axis P1 of the signal contact segment 617 passes through an end portion 618 of the signal contact segment 617. The end portion 618 is used for making electrical contact with the signal contact pads 421 of the space transformer 42. By making the central axis P1 of the signal contact segment 617 shift and be closer to the second side surface 614, not only can the alignment accuracy and flexibility between the needle tail portion 612 and the signal contact pads 421 be improved, ensuring stable conduction, but also the spatial interference and electrical short circuit risk adjacent to the tail portion of the contact probe 6 can be effectively reduced in high-density layouts, thereby enhancing overall testing reliability and durability of the probe card 4.

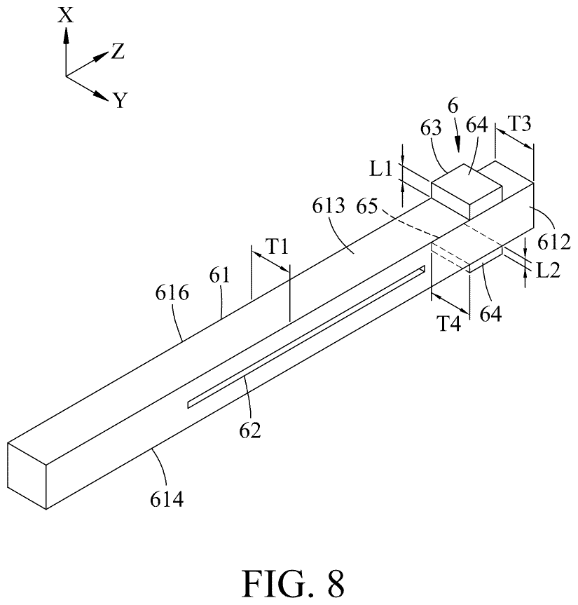

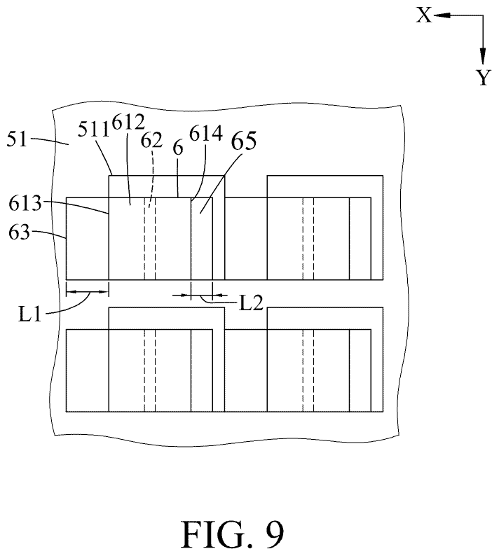

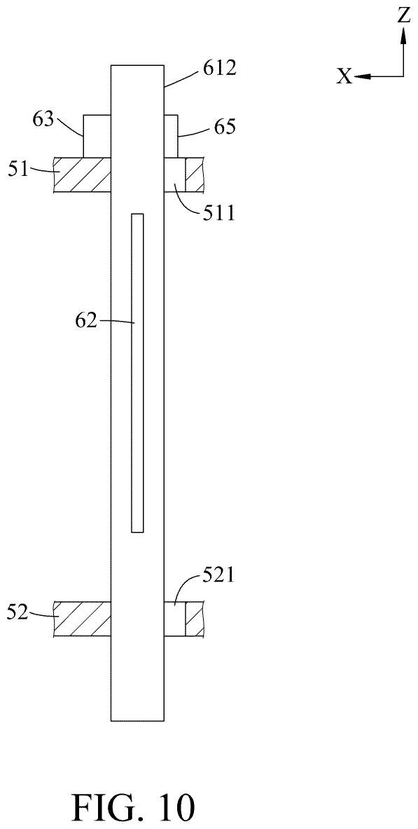

Referring to FIG. 8, FIG. 9 and FIG. 10, a third configuration of the contact probe 6 of the embodiment is shown. This third configuration of the contact probe 6 further has a second stop portion 65. FIG. 9 illustrates that, in application, the first side surface 613 of each of the contact probes 6 abuts against the hole wall surface of the upper guide plate module 51 that defines the upper guide hole 511.

The second stop portion 65 protrudes only from the second side surface 614 along a direction opposite the first transverse direction X, and is located at the needle tail portion 612 of the probe body 61. A height of a bottom end of the second stop portion 65 in the longitudinal direction Z is substantially the same as a height of a bottom end of the first stop portion 63 in the longitudinal direction Z. In application, the bottom end of the first stop portion 63 or the bottom end of the second stop portion 65 is able to contact an upper surface of the upper guide plate module 51. The insulating layer 64 is also disposed on an outer surface of the second stop portion 65 for providing the second stop portion 65 with insulation. In the drawings, the insulating layer 64 is directly indicated on the first stop portion 63 and the second stop portion 65 for illustration.

Herein, a size of the second stop portion 65 is different from a size of the first stop portion 63. As shown in FIG. 9, the two are not symmetrical with respect to the through groove 62. The length L1 of the first stop portion 63 protruding from the first side surface 613 is greater than a length L2 of the second stop portion 65 protruding from the second side surface 614. A ratio of the length L1 of the first stop portion 63 protruding from the first side surface 613 to the length L2 of the second stop portion 65 protruding from the second side surface 614 is between 2:1.2 and 2:0.8 (e.g., 2:1). This structural configuration allows the contact probe 6 to fit more tightly against the hole wall of the upper guide hole 511 during installation due to bias force, increasing frictional force which prevents dislodgement, and thus preventing the contact probe 6 from falling out during testing. At the same time, because the amount of protrusion of the second stop portion 65 is relatively small, the possibility of contact with adjacent contact probes 6 may be effectively reduced, which is particularly suitable for high-density pin header structures and may reduce the risk of short circuits caused by slight tilting or machining tolerances. Therefore, this asymmetrical and proportionally limited dual stop portion (the first stop portion 63 and the second stop portion 65) design provides an innovative solution that combines electrical safety with structural stability.

The second stop portion 65 has a thickness T4 along the second transverse direction Y. The thickness T4 is substantially equal to (or less than) the thickness T3 of the needle tail portion 612 extending along the second transverse direction Y, substantially equal to (or less than) the thickness T1 of the probe body 61 extending along the second transverse direction Y, or substantially equal to (or less than) both of the above. The thickness T4 is greater than the length L2 of the second stop portion 65 protruding from the second side surface 614.

A maximum thickness of the first stop portion 63 and a maximum thickness of the second stop portion 65 extending along the second transverse direction Y are both not greater than a maximum thickness of a corresponding one of the upper guide holes 511 along the second transverse direction Y. A maximum total width of the first stop portion 63, the needle tail portion 612 and the second stop portion 65 along the first transverse direction X is greater than a maximum width of the corresponding one of the upper guide holes 511 along the first transverse direction X.

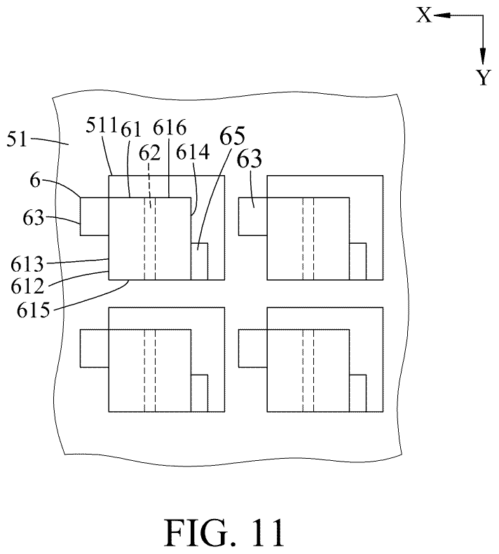

Referring to FIG. 11, a variation of the third configuration of the contact probe 6 is shown. In this variation, the first stop portion 63 and the second stop portion 65 are offset from each other in the second transverse direction Y, the first stop portion 63 is disposed to be proximate to the fourth side surface 616, and the second stop portion 65 is disposed to be proximate to the third side surface 615. In this way, the first stop portion 63 and the second stop portion 65 of two adjacent contact probes 6 arranged along the first transverse direction X are offset from each other in the second transverse direction Y, further reducing the probability of adjacent contact probes 6 coming into contact with each other.

The maximum thickness of the first stop portion 63 along the second transverse direction Y and the maximum thickness of the second stop portion 65 along the second transverse direction Y are both not greater than half of a maximum thickness of the probe body 61 along the second transverse direction Y, or not greater than half of a maximum thickness of the needle tail portion 612 along the second transverse direction Y.

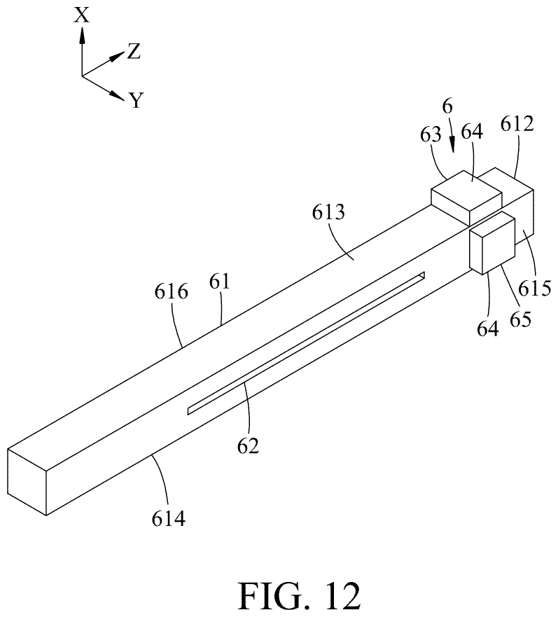

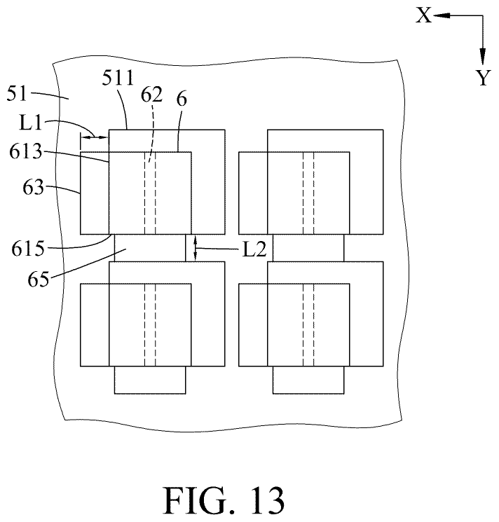

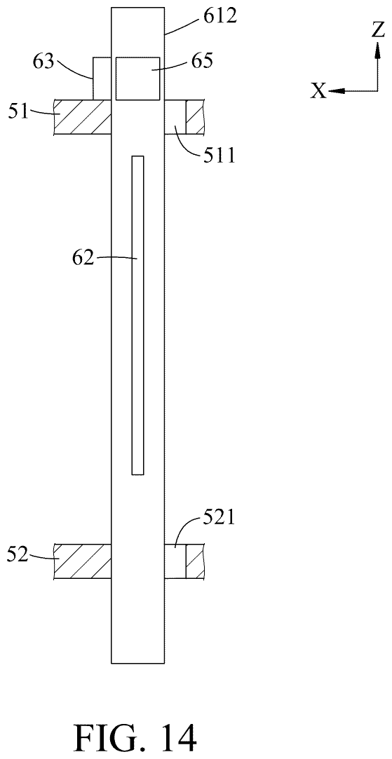

Referring to FIG. 12, FIG. 13 and FIG. 14, a fourth configuration of the contact probe 6 of the embodiment is shown. In this fourth configuration of the contact probe 6, the second stop portion 65 protrudes only from the third side surface 615 along the second transverse direction Y and is located at the needle tail portion 612 of the probe body 61. FIG. 13 illustrates that, in application, the first side surface 613 of each of the contact probes 6 abuts against the hole wall surface of the upper guide plate module 51 that defines the upper guide hole 511.

Herein, a ratio of the length L1 of the first stop portion 63 protruding from the first side surface 613 to the length L2 of the second stop portion 65 protruding from the third side surface 615 is between 0.9:1.0 and 1.1:1.0 (e.g., 1.0:1.0). To ensure that the contact probe 6 can maintain symmetrical force and precise positioning when being installed in the upper guide hole 511, and to tolerate geometric deviations in the actual manufacturing process, the present invention controls the protrusion length ratio of the first stop portion 63 and the second stop portion 65 within a range of 0.9:1.0 to 1.1:1.0, so that the contact probe 6 has basic symmetry, and the effects in preventing dislodgement, in securing, and in fitting to the upper guide hole 511 are not affected.

Herein, the maximum thickness of the first stop portion 63 along the second transverse direction Y is substantially equal to the maximum thickness of the probe body 61 along the second transverse direction Y. That is, two sides of the first stop portion 63 are basically flush with the probe body 61. A maximum width of the second stop portion 65 along the first transverse direction X is smaller than a maximum width of the probe body 61 along the first transverse direction X.

Herein, the height of the bottom end of the second stop portion 65 in the longitudinal direction Z is substantially the same as the height of the bottom end of the first stop portion 63 in the longitudinal direction Z.

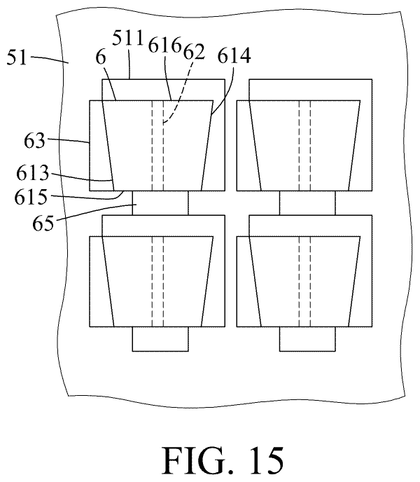

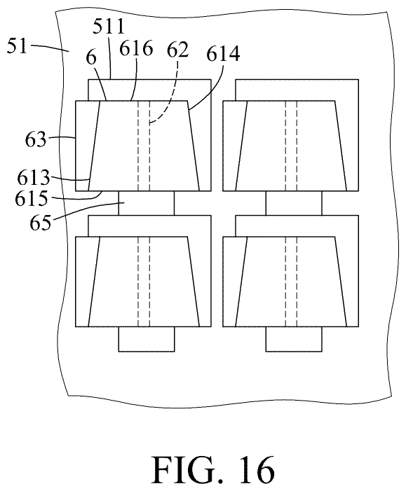

Referring to FIG. 15 and FIG. 16, possible shapes of the contact probe 6 of a fourth configuration resulting from processing errors are shown. An included angle between any two adjacent ones of the first side surface 613, the third side surface 615, the second side surface 614 and the fourth side surface 616 is not equal to 90 degrees. In FIG. 15, the included angle between the first side surface 613 and the third side surface 615 is greater than 90 degrees, the included angle between the third side surface 615 and the second side surface 614 is greater than 90 degrees, the included angle between the second side surface 614 and the fourth side surface 616 is less than 90 degrees, and the included angle between the fourth side surface 616 and the first side surface 613 is less than 90 degrees. A cross-section of the contact probe 6 is substantially trapezoidal. In FIG. 16, the aforementioned included angles are respectively less than 90 degrees, less than 90 degrees, greater than 90 degrees and greater than 90 degrees. The cross-section of the contact probe 6 is also substantially trapezoidal.

Referring to FIG. 3, FIG. 4 and FIG. 5, based on the above description, the effects of the present embodiment are as follows:

1. By providing the first stop portion 63 only on the first side surface 613, the present embodiment is capable of effectively reducing the radial thickness and width of the contact probe 6 at the first stop portion 63 (especially at the needle tail portion 612), thus reducing spacing between the contact probes 6 and increasing arrangement density of the contact probes 6. Furthermore, by incorporating the through groove 62, bending stiffness of the contact probe 6 in the first transverse direction X may be reduced. Thus, in application, when subjected to pressure from above or when in contact with the upper guide plate module 51, the needle tail portion 612 may generate controlled slight lateral deflection (a slight tilt along the first transverse direction X), causing the first side surface 613 to fit more closely against the hole wall surface of the upper guide plate module 51 that defines the upper guide hole 511. This increases the actual contact area and enhances the fit between the first side surface 613 and the hole wall surface (perpendicularly pressed against the hole wall surface), thereby increasing friction and compensating for the reduction in function of preventing dislodgement caused by the reduction in radial length and width. Therefore, the present embodiment is capable of maintaining anti-dislodgement performance comparable to conventional sizes under the condition where the size of the contact probe 6 at the first stop portion 63 (especially the needle tail portion 612) is reduced.

Furthermore, the aforementioned slight tilting causes the needle tail portion 612 to shift towards the adjacent contact probe 6, thereby shortening the distance between adjacent contact probes 6 and increasing the chance of the contact probes 6 coming into contact with each other, thus creating a risk of electrical short circuit. By disposing the insulating layer 64 on the outer surface of the first stop portion 63, the present embodiment ensures that even if the contact probes 6 come into contact with each other due to slight tilting, a short circuit will not occur and an electrical error will not be generated.

Therefore, through the abovementioned overall configuration, the present embodiment is capable of achieving a comprehensive effect that balances miniaturization, high-density arrangement, reliable prevention of dislodgment, and electrical safety, etc.

2. By setting the thickness T1 of the contact probe 6 to be greater than or equal to the width W1, in application, a thicker side of the contact probe 6 will abut against the upper guide plate module 51. This provides greater friction, and thus a smaller-sized first stop portion 63 is sufficient to prevent the contact probe 6 from falling out of the upper guide holes 511. That is, the above structure may further reduce the radial space occupied by the contact probe 6 at the first stop portion 63 (especially the needle tail portion 612), thereby reducing spacing between the contact probes 6.

3. Referring to FIG. 8 and FIG. 12, by adding the second stop portion 65, the effect of preventing the contact probe 6 from falling out of the upper guide hole 511 may be further improved.

In summary, the contact probe, the probe head, the probe card and the probe system of the present invention, through their innovative structural designs and mechanism configurations, are capable of effectively solving the structural limitations and performance trade-offs faced by miniaturization of probes and high-density layouts in the prior art, thereby achieving multiple technical requirements of structural stability, electrical reliability and process tolerance under high-density testing layouts.

However, the above description is merely an embodiment of the present invention, and certainly, the scope of the present invention in practice cannot be limited thereby. Any simple equivalent variation and modification made according to the claims of the present invention and the contents of patent specification should fall within the scope covered by a patent to the present invention.

1. A contact probe adapted for contacting and testing a device under test, comprising:
a probe body that extends along a longitudinal direction, a first transverse direction being defined as intersecting the longitudinal direction, a second transverse direction being defined as intersecting the longitudinal direction and the first transverse direction, the probe body including a needle tip portion and a needle tail portion that are respectively located at two opposite ends thereof along the longitudinal direction, and a first side surface and a second side surface that are respectively located at two opposite ends in the first transverse direction, the needle tip portion being adapted for contacting the device under test;
a through groove that runs through the probe body along the second transverse direction and that extends along the longitudinal direction;
a first stop portion that protrudes only from the first side surface along the first transverse direction and that is located at the needle tail portion of the probe body; and
an insulating layer that is a metal oxide and that is disposed on an outer surface of the first stop portion.

2. The contact probe as claimed in claim 1, wherein the probe body has a width along the first transverse direction and a thickness along the second transverse direction, the thickness being greater than or equal to the width.

3. The contact probe as claimed in claim 1, further comprising a second stop portion, the second stop portion protruding only from the second side surface along a direction that is opposite the first transverse direction, and being located at the needle tail portion of the probe body.

4. The contact probe as claimed in claim 3, wherein a height of a lowest point of the second stop portion in the longitudinal direction is substantially the same as a height of a lowest point of the first stop portion in the longitudinal direction.

5. The contact probe as claimed in claim 3, wherein a size of the second stop portion is different from a size of the first stop portion.

6. The contact probe as claimed in claim 5, wherein a length of the first stop portion protruding from the first side surface is greater than a length of the second stop portion protruding from the second side surface.

7. The contact probe as claimed in claim 6, wherein a ratio of the length of the first stop portion protruding from the first side surface to the length of the second stop portion protruding from the second side surface is between 2:1.2 and 2:0.8.

8. The contact probe as claimed in claim 6, wherein the first stop portion has a thickness along the second transverse direction, the thickness being less than a thickness of the needle tail portion along the second transverse direction, less than the thickness of the probe body extending along the second transverse direction, or less than both of the above.

9. The contact probe as claimed in claim 8, wherein the first stop portion and the second stop portion are offset from each other in the second transverse direction.

10. The contact probe as claimed in claim 1, wherein the first stop portion has a thickness along the second transverse direction, the thickness being substantially equal to a thickness of the needle tail portion extending along the second transverse direction, substantially equal to a thickness of the probe body extending in the second transverse direction, or substantially equal to both of the above.

11. The contact probe as claimed in claim 1, wherein a length of the first stop portion protruding from the first side surface is less than a thickness of the first stop portion extending along the second transverse direction.

12. The contact probe as claimed in claim 1, wherein the needle tail portion has a signal contact segment, the signal contact segment being located at an end of the needle tail portion that is away from the needle tip portion, a central axis of the signal contact segment having an offset amount from a central axis of the probe body along a first transverse direction.

13. The contact probe as claimed in claim 1, further comprising a second stop portion, the probe body further including a third side surface that is adjacent to the first side surface and the second side surface, the second stop portion protruding only from the third side surface along the second transverse direction and being located at the needle tail portion of the probe body.

14. The contact probe as claimed in claim 13, wherein a ratio of a length of the first stop portion protruding from the first side surface to a length of the second stop portion protruding from the third side surface is between 0.9:1.0 and 1.1:1.0.

15. The contact probe as claimed in claim 13, wherein a height of a bottom end of the second stop portion in the longitudinal direction is substantially the same as a height of a bottom end of the first stop portion in the longitudinal direction.

16. The contact probe as claimed in claim 13, wherein an included angle between the first side surface and the third side surface is not equal to 90 degrees.

17. A probe head adapted for contacting and testing a device under test, comprising:
an upper guide plate module that includes a plurality of upper guide holes;
a lower guide plate module that is spaced apart from the upper guide plate module along a longitudinal direction, the lower guide plate module including a plurality of lower guide holes, positions respectively of the lower guide holes respectively corresponding to positions respectively of the upper guide holes;
a middle guide plate module that is disposed between the upper guide plate module and the lower guide plate module, thereby spacing apart the upper guide plate module and the lower guide plate module;
a plurality of contact probes as claimed in claim 1, each of the contact probes passing through one of the upper guide holes and a corresponding one of the lower guide holes.

18. The probe head as claimed in claim 17, wherein in each of the contact probes, the probe body has a width along the first transverse direction and a thickness along the second transverse direction, the thickness being greater than or equal to the width, the first side surface abutting against the upper guide plate module.

19. The probe head as claimed in claim 18, each of the contact probes further including a second stop portion, the second stop portion protruding only from the second side surface along a direction that is opposite the first transverse direction, and being located at the needle tail portion of the probe body, a maximum thickness of the first stop portion and a maximum thickness of the second stop portion along the second transverse direction both being not greater than a maximum thickness of a corresponding one of the upper guide holes along the second transverse direction.

20. The probe head as claimed in claim 19, wherein a maximum total width of the first stop portion, the needle tail portion and the second stop portion along the first transverse direction is greater than a maximum width of the corresponding one of the upper guide holes along the first transverse direction.

21. The probe head as claimed in claim 17, wherein the probe body further includes a third side surface that is adjacent to the first side surface and the second side surface, each of the contact probes further including a second stop portion, the second stop portion protruding only from the third side surface along the second transverse direction and being located at the needle tail portion of the probe body.

22. A probe card adapted for contacting and testing a device under test, comprising:
a main circuit board;
a space transformer that is electrically connected to the main circuit board and that includes a plurality of signal contact pads; and
the probe head as claimed in claim 17, the needle tail portions of the contact probes being respectively used for contacting the signal contact pads.

23 The probe card as claimed in claim 22, wherein each of the needle tail portions has a signal contact segment, the signal contact segment being located at an end of the needle tail portion that is away from the needle tip portion and for contacting the signal contact pad, a central axis of the signal contact segment having an offset amount from a central axis of the probe body along the first transverse direction.

24. A probe system adapted for contacting and testing a device under test, the device under test including a plurality of contact points, the probe system comprising:
a carrier unit adapted for the device under test to be disposed thereon;
a testing machine used for executing a testing program and outputting a program signal; and
the probe card as claimed in claim 22 disposed to correspond to the carrier unit, the contact probes being adapted to contact the contact points, the main circuit board being signally connected to the testing machine, receiving the program signal, outputting a testing signal based on the program signal, and transmitting the testing signal via the space transformer and the contact probes to test the device under test.

25. The probe system as claimed in claim 24, wherein in at least some of the contact probes, the needle tip portion contacts a plurality of the contact points.
